(19) United States
(12) Patent Application Publication
(10) Pub. No.: US 2020/0204105 A1
(43) Pub. Date: Jun. 25, 2020

(54) SEAMLESS ENCAPSULATION OF PHOTOVOLTAIC MODULES FOR PAVING SURFACES

(71) Applicant: SOLAR EARTH TECHNOLOGIES LTD., Vancouver (CA)

(72) Inventors: Yao Wang, Chongqing (CN); Xinghua Wang, Vancouver (CA); Shaoli CHEN, Chongqing (CN); Meng Wang, Vancouver (CA)

(21) Appl. No.: 16/612,527

(22) PCT Filed: May 11, 2018
(86) PCT No.: PCT/CA2018/050562

§ 371 Date: Nov. 11, 2019

Related U.S. Application Data
(60) Provisional application No. 62/505,621, filed on May 12, 2017.

(51) Int. Cl. H02S 20/21; E01C 5/22; E01C 11/00; B32B 7/12

(52) U.S. Cl. CPC H02S 20/21; E01C 5/22; B32B 2457/12; B32B 7/12; E01C 11/00

(57) ABSTRACT

The present invention provides a photovoltaic module for paving surfaces that supports pedestrians and vehicles, comprising one or more photovoltaic cells interconnected in serial or in parallel and placed in the same plane including: an upper protective layer that is non-opaque and is seamlessly adhered to both the photovoltaic cells and another protective mounting layer that is and is seamlessly adhered from the bottom and sides. A further binding layer underneath the second protective layer, an anti-skid layer seamlessly adhered at the very top to the entire structure with irregular textures of various granularities, and a baseplate seamlessly adhered from the very bottom to the entire structure allow a glutinous material to be applied when paving a road surface with the disclosed modules.

### FIELD OF THE INVENTION

The present invention pertains to the field of encapsulating photovoltaic solar cells and in particular, to a method of encapsulating photovoltaic solar cells and producing modules suitable for paving surfaces that are able to support pedestrian and vehicle transportation.

### BACKGROUND

Since middle 2000's there have been numerous attempts to use specially customized photovoltaic panels to pave road surfaces and so turn paved roads into a place for harvesting solar energy while retaining their traditional functions as a means of transportation and commuting.

All the prior art follows a similar approach to paving whereby a number of pre-fabricated photovoltaic panels or “modules” are used to either replace the upper layer of a conventional road surface or are paved directly upon existing road surfaces. Further all prior works follow the same principle for structural design whereby standard photovoltaic solar cells are sealed in a water-proof encapsulation with the top side of the module being transparent to allow penetration by incident sunlight. The uppermost side of the module must also: (1) be strong enough to withstand and protect the photovoltaic cells within from the loads and other mechanical stresses typically endured by roadways; and (2) provide a sufficient coefficient of friction implement an anti-skidding strategy to prevent pedestrians and vehicles from losing traction and causing accidents.

Therefore, there is a need for a superior method of encapsulating photovoltaic cells that ensures: complete protection from environmental and mechanical stresses, maximized photovoltaic conversion of photons to useful electricity; and sufficient coefficients of friction to minimize accidents.

This back-ground information is provided to reveal information believed by the applicant to be of possible relevance to the present invention. No admission is necessarily intended, nor should be construed, that any of the preceding information constitutes prior art against the present invention.

### SUMMARY OF THE INVENTION

An object of the present invention is to provide a seamless encapsulation of photovoltaic modules for paving surfaces. In accordance with an aspect of the present invention, there is provided a method of manufacturing photovoltaic modules used for paving pedestrian or vehicle pathways comprised of: aligning one or more photovoltaic cells placed in a plane; seamlessly adhering a non-opaque, optical layer to the top surface and the side surfaces of the photovoltaic cells; and seamlessly adhering a mounting layer to the bottom of the photovoltaic cells and to the exposed bottom surfaces of the optical layer.

In accordance with another aspect of the present invention, there is provided a photovoltaic apparatus for paving pedestrian or vehicle pathways comprising: one or more photovoltaic cells placed in a plane; a non-opaque, optical layer seamlessly adhered to the top surface and the side surfaces of the photovoltaic cells; and a mounting layer seamlessly adhered to the bottom of the photovoltaic cells and to the exposed bottom surfaces of the optical layer.

### BRIEF DESCRIPTION OF THE FIGURES

FIG. 1 illustrates a cross-section view of the structure of the dual-element seamless encapsulation of solar road modules.

FIG. 2 illustrates a general workflow for making a complete solar road module.

FIG. 3 illustrates the three-step process of a dual-element, seamless encapsulation.

FIG. 4 illustrates an alternative configuration for a two-element seamless encapsulation.

FIG. 5 illustrates the bottom of baseplate as prepared with textured patterns for applying binding agent during the paving process.

FIG. 6 illustrates various patterns to place encapsulations onto baseplate to form a solar road module.

FIG. 7 illustrates the integration of completed encapsulations with the baseplate.

FIG. 8 illustrates an inter-encapsulation level anti-skidding pattern.

FIG. 9 illustrates several intra-encapsulation level anti-skidding options.

FIG. 10 illustrates microgranular level anti-skidding patterns made with particles of various shapes.

FIG. 11 illustrates microgranular level anti-skidding patterns made using pre-fabricated molds.

### DETAILED DESCRIPTION OF THE INVENTION

Unless defined otherwise, all technical and scientific terms used herein have the same meaning as commonly understood by one of ordinary skill in the art to which this invention belongs.

The present invention provides a dual-element, seamless encapsulation process for packaging solar road modules that combines the advantages of using a first-element material for the sides and the bottom of the encapsulation and uses the second-element material when encapsulating the entirely of the module. The first-element material need not be the same as the second-element material allowing the top of the encapsulation to remain transparent while the bottom and the sides need not be so.

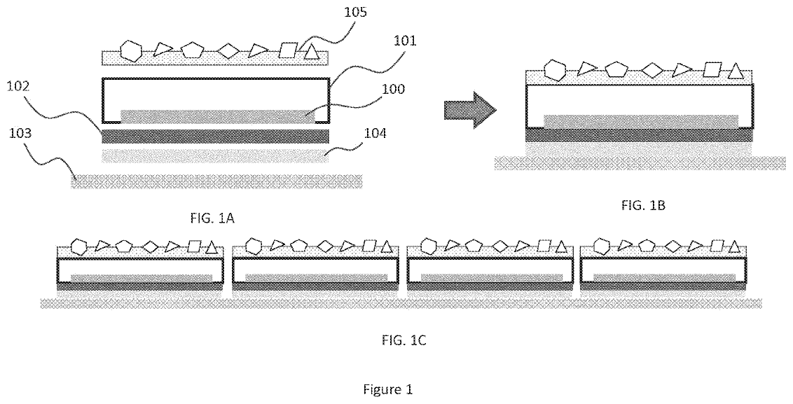

FIG. 1(A) shows the cross-section view of the overall structure of the proposed two-element seamless encapsulation of photovoltaic cells for making solar road modules. One or a plurality of photovoltaic cells (100) are protected and encapsulated from top and sides by a first element material (101) and from bottom by a second element material (102). By design, while the function of the first element protection layer (101) is to prevent the photovoltaic cells (100) from being damaged by loads on the road surfaces (pedestrians and vehicles) and to provide a transparent media for the incident sunlight to land on the photovoltaic cells, the function of the second element protection layer (102) is to offer a pressure-conducting and toughening layer to relay the pressure uniformly to the layers underneath. This difference in functional requirement prescribes completely different parameters when choosing the materials best suitable for the first element and for the second element, respectively. A fundamental difference is that the materials for making the first element have to be as transparent as possible, whereas the materials for making the second element do not have to be transparent at all.

These two element protection layers are directly adhered to the photovoltaic cells from above and from below, forming a seamless encapsulation with one or a plurality of photovoltaic cells inside this encapsulation. The first (top) element, the photovoltaic cells themselves, and the second (bottom) element, are the core components of the present invention. Peripheral components include an anti-skidding layer (105) that is seamlessly adhered to the first element protection layer from above, and a baseplate (103) that resides underneath the second element layer and serves the functions of (1) integrating one or a plurality of encapsulations into one solar road module, and (2) interfacing the solar road module and the original road surface or the exposed road base. A binding layer (104) resides between the encapsulation and the baseplate serving the functions of (1) gluing the encapsulations to the baseplate and (2) offering a damping buffer that minimizes the propagation of vibrations throughout the apparatus.

The baseplate (103) is a rigid or flexible bed to host one (FIG. 1(B)) or a plurality of encapsulations (FIG. 1(C)). In a typical paving application there are multiple encapsulations arrayed on one baseplate to form a solar road module which serves as a functional and structural unit while paving.

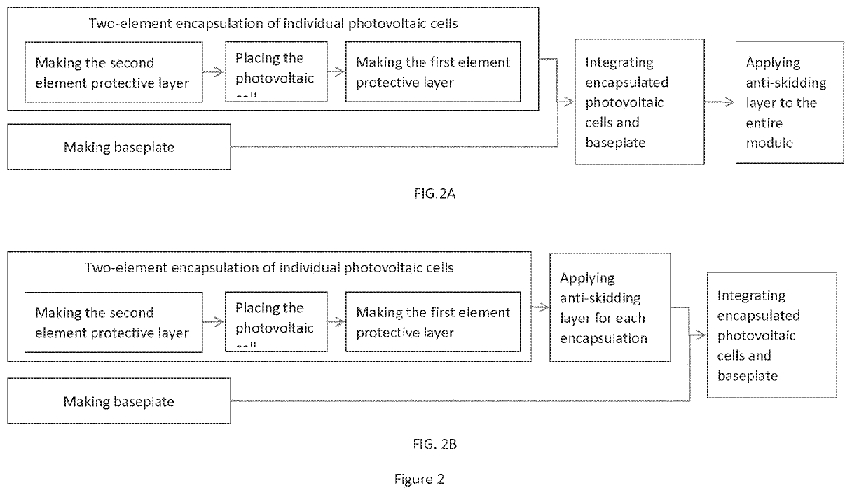

FIG. 2 shows the block diagrams of a three-step process of making a two-element seamless encapsulation and a four-step process of fabricating a complete solar road module. In a typical embodiment, the second (bottom) element protective layer is made first, then the photovoltaic cells are placed on top of the finished second element protective layer, and then the first element protective layer is made and applied to the top of the photovoltaic cells and to the exposed portions of the second element thus forming a complete encapsulation.

A preferred embodiment of the present invention contemplates a four-step process of fabricating a complete solar road module. The required steps to fabricating the two-element seamless encapsulations are carried out in parallel with making the baseplate (103). There is no inherent interdependence between these two steps and so they may be assigned to two workshops to process in parallel. FIG. 2(A) illustrates the subsequent process whereby the finished encapsulations and baseplates are integrated to form solar road modules. Finally, the anti-skidding layer is adhered to the top of the entire module.

An alternative embodiment of the invention is shown in FIG. 2(B), where the first two steps of the process remain the same as in FIG. 2A). In this embodiment the anti-skidding layer is applied first to each encapsulation, followed by integration with the baseplate.

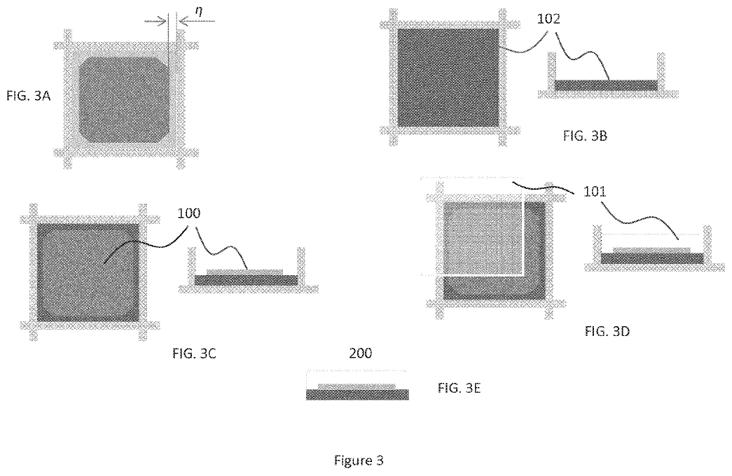

FIG. 3 is a detailed description of the method of manufacture of a two-element seamless encapsulation. Without loss of generality, we disclose an embodiment where only one photovoltaic cell is encapsulated, noting that the same principles may be applied to instances when a plurality of photovoltaic cells are sealed using the same encapsulation process.

A fundamental nature of this invention is that the two element protective materials are characteristically different from above and from below the photovoltaic cells under protection, and that they should be seamlessly adhered to the photovoltaic cells. Essentially, the function of the first element protection layer from above (101) is to prevent the photovoltaic cells (100) from being damaged by loads on the road surfaces (pedestrians and vehicles) and to provide a transparent media for the incident sunlight to land on the photovoltaic cells, and the function of the second element protection layer from bottom (102) is to offer a pressure-conducting and strengthening layer to distribute mechanical forces uniformly to the layers underneath.

This design principle leads to two consequences: (1). it prescribes the criteria when choosing the best materials for the first element and for the second element, respectively. (2). the thickness of the first element and the second element need not be uniform, with the first element typically being thicker than the second. In a preferred embodiment, the empirical thickness of the first element ranges from 3 to 6 mm, whereas that of the second element ranges from 2 to 4 mm.

In a typical embodiment, a mold is employed in the three-step process of the two-element seamless encapsulation, as shown in FIG. 3A). The depth of the mold is to be no less than the total thickness of the completed encapsulation, and the size of the mold is such determined that the margin η when the photovoltaic cell is placed into the mold is to be no less than the thickness of the element one protective layer.

FIG. 3(B) shows the top view and side view of step one of the three-step process, where the second element layer (102) is first placed to the bottom of the mold. The material for the second element should be non-conductive. There are two typical embodiments for the implementation of this second element. One is to use materials in a solid-state such as nylons, rubbers, plastic materials, or any mixtures of them, another is to use liquid-state materials which freeze or solidify after being applied to the mold, such as non-conductive polymers and epoxies. FIG. 3(C) shows the top view and side view of step two of the three-step process, where the photovoltaic cell (100) is placed on top of the second element. It is particularly noted that if the second (bottom) element material used in step one is liquid, then placing the photovoltaic cell must until the liquid second (bottom) element material has solidified. FIG. 3(D) shows the top view and side view of the third of the three-step process, where the first (top) element layer (101) is applied to completely and seamlessly cover the photovoltaic cell (100) from above and from the sides. The material for the first (top) element should be non-conductive, strong, and as transparent as possible. There are two typical embodiments for the implementation of this first element material. One is to use solid-state materials such as tempered glass plates with drip edges, and another is to use liquid-state materials such as non-conductive, transparent polymers which solidify after being applied to the mold. It is required that where the first (top) element and the second (bottom) element meet must be seamlessly sealed.

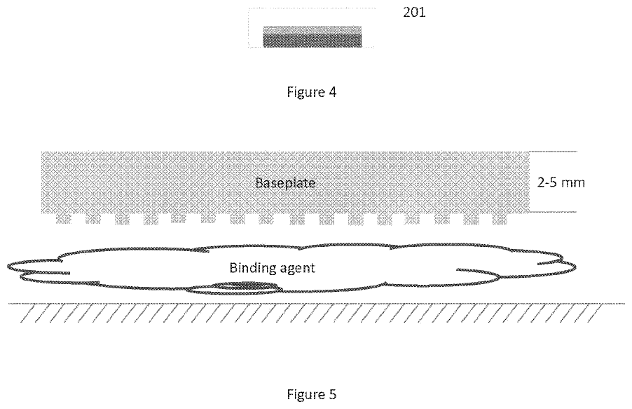

FIG. 3(E) shows the finished encapsulation (200) after removing the mold. One alternate configuration (201) is shown in FIG. 4, where the first element material covers not only the photovoltaic cell but also the top and sides of the second element.

The baseplate (103) is the interface between the encapsulations and the original road surface or road base. One critical function of the baseplate is to ensure its good adhesion to the road surface or road base against possible displacement in horizontal directions under shearing stress caused by loads that move on the solar road. In order to provide such adhesion, the bottom of the baseplate 103 is prepared with textured patterns as shown in FIG. 5. During actual paving, these textured patterns ensure that the binding agent such as mortars would grip tightly the solar road modules to the road surface or road base. In typical embodiments, the baseplate may be made of mixtures of glass fibers with resins, polyurethanes, viscous agents, or other polymers in combination with functional additives such as flame retardants and plasticizers.

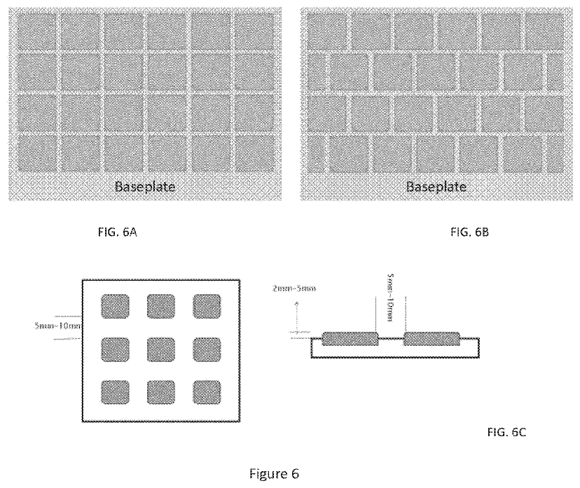

FIGS. 6A) and (B) illustrate some possible configurations when laying out encapsulations onto a baseplate to form a solar road module. Small gaps (typically 5 mm-10 mm wide and 2 mm-5 mm deep) are intentionally left in between encapsulations (FIG. 6(C)) for purposes of (1) providing a micro drainage network, and (2) keeping as much as possible dirt and dust away from surface of the encapsulations. These gaps also play an important role in anti-skidding design.

When integrating the encapsulations with the baseplate, the binding layer (104) between the encapsulations and the baseplate not only adhesively secures the encapsulations with the baseplate, but also offers a damping buffer that minimizes the propagation of vibrations across multiple encapsulations and throughout the module. In typical embodiments, the materials for the binding layer can include polymers, silica gel, polyurethane, and organic materials with similar properties.

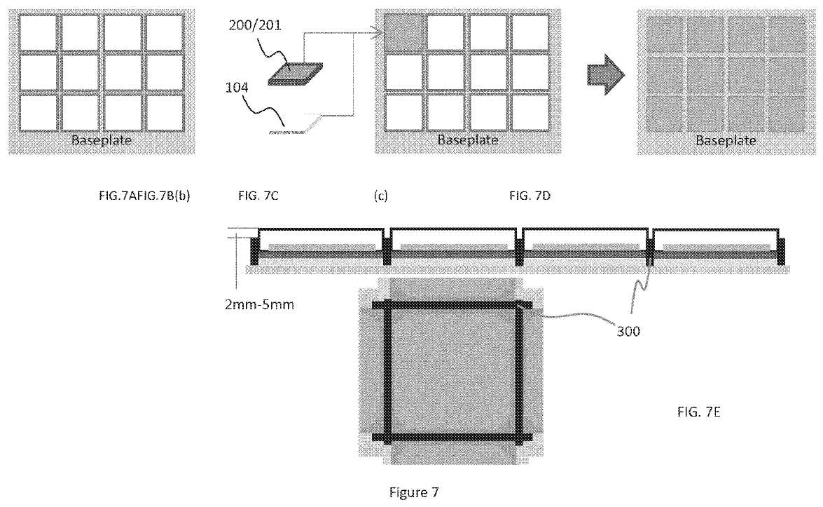

FIG. 7 shows the integration process, starting with a fabricated baseplate and a standard configuration (FIG. 7A)). For each encapsulation (200/201), the binding layer (104) is applied to its back side (FIG. 7(B)), and then the encapsulation is glued to its designated location on the baseplate (FIG. 7(C)). This process is repeated until all designated places on the baseplate are filled with encapsulations (FIG. 7(D)). Once all encapsulations are adhered to the baseplate, a filler coating (300) is applied to the entire module filling all spaces between the encapsulations (FIG. 7(E)). The thickness of the filler coating (300) is determined such that the encapsulations are about half immersive into the coating. For example, in one embodiment, when the thickness of an encapsulation is 8 mm, then the thickness of the filler coating (300) is approximately 4 mm.

Anti-slip or anti-skidding is a basic and important requirement for any solar module used to pave road surfaces. In general, this requirement means enough surface friction on the road surface as result of pre-fabricated texture patterns or small artificial objects such as obstacles, bars, grooves, or gaps at various spatial scales and granularities. A preferred embodiment of the current invention employs a three-level anti-skidding strategy:

When forming a solar road module, the gaps between encapsulations establish a discontinuity at an interval length equal to the dimensions of the encapsulations. This periodic discontinuity, throughout the entire solar road pavement, forms a first level of anti-skidding patterns as illustrated in FIG. 8.

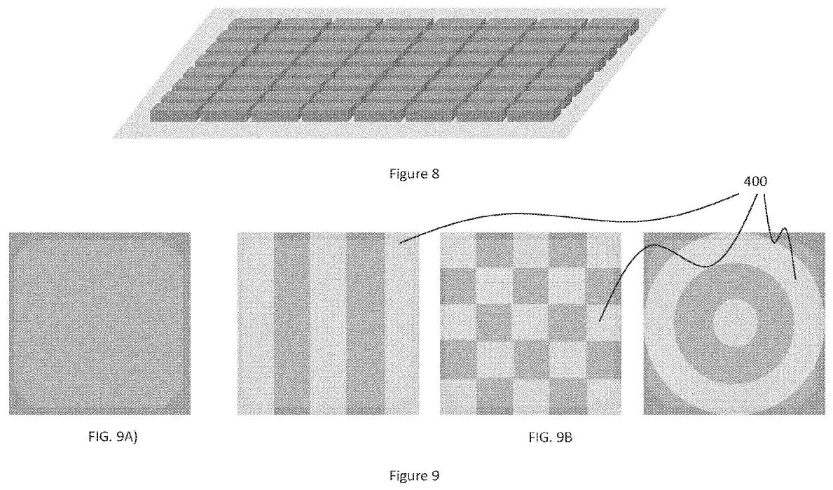

Without any further processing, the top of each encapsulation will be smooth and devoid of anti-skidding characteristics. Thus, a preferred embodiment applies some micro-granularity level anti-skidding patterns to the top of each encapsulation. If the apparatus is fully covered with micro-granularity level anti-skidding patterns, will have a negative impact on the optical properties of the encapsulation. By coating only some areas with micro-granularity level anti-skidding patterns, we have created an intra-encapsulation level anti-skidding effect. FIG. 9A shows the top of a finished encapsulation without any micro-granularity level anti-skidding patterns, and FIG. 9B shows some embodiments of intra-encapsulation level anti-skidding patterns, where only the areas (400) are applied with micro-granularity level anti-skidding patterns while the remainder are left untreated.

The anti-skidding patterns at the micro-granularity level consist of micro and randomly distributed surface structures on top of encapsulations to provide surface friction for the areas where these micro structures are applied. The granularity of these micro structures ranges from 0.5-2 mm and provide better the surface friction if they have randomly differing geometric shapes. There are two ways of realizing the micro-granularity anti-skidding layer:

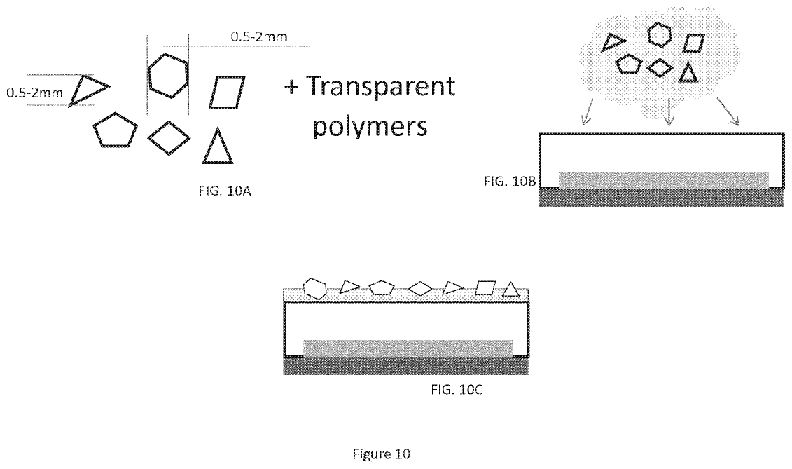

As shown in FIG. 10 A, a plurality of mini, hard, and transparent particles in random shapes like polyhedrons and spatial scales from 0.5-2 mm, made of tempered glasses, fused silica, or quartz, etc., are mixed with non-conductive and transparent liquid-state materials which are the same materials used for making the first element protective layer of the encapsulation, such as transparent polymers. This mixture is applied to the top surface of encapsulation in FIG. 10 B to form a transparent coating at thickness about 0.5-2 mm and so to increase surface friction for the areas where the coating is applied as in FIG. 10C.

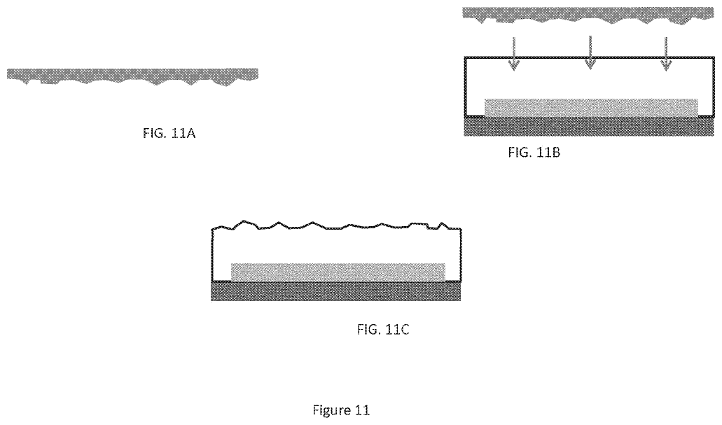

If the material for making the first element of the encapsulation is liquid-state before it freezes, then an alternative method for realizing micro-granularity anti-skidding patterns is shown in FIG. 11. A mold is prepared with its one surface consisting of micro and randomly distributed surface patterns with typical spatial scales at 0.5-2 mm and depth at 0.5-2 mm (FIG. 11A)). Before the first element of the encapsulation freezes, this mold is applied from top side to the first element with its textured surface facing the surface of the encapsulation (FIG. 11(B)). Once being placed, the mold needs to stay still until the first (top) element completely freezes. After demolding, the surface of the first (top) element of the encapsulation is carved with desired anti-skidding patterns (FIG. 11(C)).

As shown in FIG. 2, the anti-skidding layer may be applied to the top of the encapsulation either: after it is integrated with the baseplate (FIG. 2A)); or before (FIG. 2(B)). In the second case, the anti-skidding layer must be pre-fabricated in factory before the modules are shipped to the site of pavement, whereas in the first case, application of anti-skidding layer may be done either in the factory or on site.

It will be understood that the foregoing embodiments of the invention are examples and can be varied in many ways. Such present or future variations are not to be regarded as a departure from the spirit and scope of the invention, and all such modifications as would be obvious to one skilled in the art are intended to be included within the scope of the following claims.

We claim:

1. A method of manufacturing photovoltaic modules used for paving pedestrian or vehicle pathways comprising:
aligning one or more photovoltaic cells placed in a plane;
seamlessly adhering a non-opaque, optical layer to the top surface and the side surfaces of the photovoltaic cells; and
seamlessly adhering a mounting layer to the bottom of the photovoltaic cells and to the exposed bottom surfaces of the optical layer.

2. A method of manufacturing photovoltaic modules used for paving pedestrian or vehicle pathways as claimed in claim 1 wherein each of the optical layer, the photovoltaic cells and the mounting layer are seamlessly adhered so that no voids or spaces empty of matter exist within the encapsulated photovoltaic apparatus.

3. A method of manufacturing photovoltaic modules used for paving pedestrian or vehicle pathways as claimed in claim 1 where a binding layer is seamlessly adhered to the exposed bottom of the mounting layer.

4. A method of manufacturing photovoltaic modules used for paving pedestrian or vehicle pathways as claimed in claim 1 where a binding layer with force damping and distribution properties is seamlessly adhered to the exposed bottom of the mounting layer.

5. A method of manufacturing photovoltaic modules used for paving pedestrian or vehicle pathways as claimed in claim 1 where a baseplate is affixed to the bottom-most layer of the apparatus and where glutinous and adhesive materials may be applied when paving a road surface allowing the photovoltaic apparatus to tightly grip the road surface or road base.

6. A method of manufacturing photovoltaic modules used for paving pedestrian or vehicle pathways as claimed in claim 1 where a baseplate affixed to the bottom most layer of the apparatus has a bottom surface textured in a manner to optimize adhesion to the road surface or road bed.

7. A method of manufacturing photovoltaic modules used for paving pedestrian or vehicle pathways as claimed in claim 1 where an anti-skidding layer with irregular textures of various granularities is adhered to the topmost surface of the apparatus.

8. A method of manufacturing photovoltaic modules used for paving pedestrian or vehicle pathways as claimed in claim 1 where the backside of the baseplate is prepared with textured patterns that offer good adhesion for the solar road module to grip tightly to the road surface or road base.

9. A photovoltaic apparatus for paving pedestrian or vehicle pathways comprising:
one or more photovoltaic cells placed in a plane;
a non-opaque, optical layer seamlessly adhered to the top surface and the side surfaces of the photovoltaic cells; and
a mounting layer seamlessly adhered to the bottom of the photovoltaic cells and to the exposed bottom surfaces of the optical layer.

10. A photovoltaic apparatus for paving pedestrian or vehicle pathways as claimed in claim 9 wherein each of the optical layer, the photovoltaic cells and the mounting layer are seamlessly adhered so that no voids or spaces empty of matter exist within the encapsulated photovoltaic apparatus.

11. A photovoltaic apparatus for paving pedestrian or vehicle pathways as claimed in claim 9 where a binding layer is seamlessly adhered to the exposed bottom of the mounting layer.

12. A photovoltaic apparatus for paving pedestrian or vehicle pathways as claimed in claim 9 where a binding layer with force damping and distribution properties is seamlessly adhered to the exposed bottom of the mounting layer.

13. A photovoltaic apparatus for paving pedestrian or vehicle pathways as claimed in claim 9 where a baseplate is affixed to the bottom-most layer of the apparatus and where glutinous and adhesive materials may be applied when paving a road surface allowing the photovoltaic apparatus to tightly grip the road surface or road base.

14. A photovoltaic apparatus for paving pedestrian or vehicle pathways as claimed in claim 9 where a baseplate affixed to the bottom most layer of the apparatus has a bottom surface textured in a manner to optimize adhesion to the road surface or road bed.

15. A photovoltaic apparatus for paving pedestrian or vehicle pathways as claimed in claim 9 where an anti-skidding layer with irregular textures of various granularities is adhered to the topmost surface of the apparatus.

16. A photovoltaic apparatus for paving pedestrian or vehicle pathways as claimed in claim 9 where the backside of the baseplate is prepared with textured patterns that offer good adhesion for the solar road module to grip tightly to the road surface or road base.
